(19) United States
(12) Patent Application Publication
(10) Pub. No.: US 2007/0035009 A1
(43) Pub. Date: Feb. 15, 2007

(54) Printed circuit board, semiconductor package and multi-stack semiconductor package using the same

(76) Inventors: Sung-wook Hwang, Seongnam-si (KR); Sang-ho An, Suwon-si (KR)

Correspondence Address: HARNESS, DICKEY & PIERCE, P.L.C., P.O. BOX 8910, RESTON, VA, 20195, US

(21) Appl. No.: 11/502,399

(22) Filed: Aug. 11, 2006

(30) Foreign Application Priority Data
Aug. 12, 2005 (KR) 2005-0074479

(51) Int. Cl. H01L 23/12

(52) U.S. Cl. 257/700

(57) ABSTRACT

In an example embodiment, a printed circuit board (PCB) includes a package substrate having a plurality of first solder balls and a first resist layer formed on the first side. The first resist layer may have a plurality of first elliptical openings. Each of the first elliptical openings exposes a portion of one of the solder ball lands, respectively. In a related example embodiment, the first solder ball lands may be disposed along at least one direction of the first side and long axis of the first elliptical openings are disposed having a declination of 30° to 60° with respect to the at least one direction. In yet another example embodiment, the PCB may also have a plurality of second solder ball lands formed on a second side of the package substrate, along with a second resist layer formed on the second side of the package and including a plurality of second elliptical openings exposing a portion of one of the second solder ball lands, respectively. The PCB may also include a mounting region for a semiconductor chip located on the second side of the package substrate.

### CROSS-REFERENCE TO RELATED PATENT APPLICATION

This application claims the benefit of Korean Patent Application No. 10-2005-0074479, filed on Aug. 12, 2005, in the Korean Intellectual Property Office, the disclosure of which is incorporated herein in its entirety by reference.

### BACKGROUND OF THE INVENTION

1. Field of the Invention

The present invention relates to a semiconductor package, and more particularly, to a printed circuit board (PCB), a semiconductor package, and a multi-stack semiconductor package (MSP) including a plurality of semiconductor packages.

2. Description of the Related Art

Recent years have seen an accelerating trend towards smaller semiconductor products, along with an increasing demand for highly integrated semiconductor chips and smaller package modules. MSP technology attempts to meet this demand by stacking a plurality of semiconductor packages to form one package module.

MSP technology is directed towards stacking similar memory chip packages or different semiconductor chip packages (e.g., a memory chip package and a logic chip package). An MSP formed by stacking semiconductor chip packages of different kinds is referred to as a package on package (POP).

Various types of MSP devices can be formed. For example, an MSP can be formed by stacking semiconductor chip packages and then connecting the semiconductor chip packages to each other using multi-step wire bonding. Alternatively, a ball grid array (BGA) type MSP can be formed by connecting semiconductor chip packages to each other using conductive solder balls.

In the highly integrated semiconductor chips of a BGA type MSP, the large number of metal pads requires a correspondingly large number of solder balls. In a POP structure, a dense arrangement of solder balls is necessary because an upper semiconductor package is connected to the outer edge region of a lower semiconductor package. Moreover, the solder balls of the upper semiconductor package are taller (and therefore larger) than the solder balls of the lower semiconductor package. Such dense solder ball arrangements may cause a short-circuit between the individual solder balls.

Referring to FIG. 1, a plurality of solder ball lands 54 are exposed through openings 58 formed in a resist layer 52 on the backside of a PCB 50 of an MSP. The solder ball lands 54 and the openings 58 have a circular shape.

Referring to FIG. 2, solder balls 56 are bonded on the solder ball lands 54 exposed through the openings 58. The circular-shaped solder balls 56 are disposed on the solder ball lands 54. Then, a reflow process is performed to bond the solder balls 56 to the solder ball lands 54. As a result, adjacent solder balls 56 may inadvertently be connected to each other during the reflow process, causing a short-circuit 56′.

If the diameter of the solder ball 56 is 0.32 mm and the pitch W1 between the solder balls 56 is 0.65 mm, then the resulting separation distance W2 between the solder balls 56 is 0.15 mm, which is very small. Therefore, a need exists for an MSP capable of reducing the likelihood of a short-circuit between the solder balls 56 having a fine pitch W1.

### SUMMARY OF THE INVENTION

The present invention is directed to a printed circuit board, semiconductor package, and multi-stack semiconductor package using the same.

In an example embodiment, a printed circuit board (PCB) includes a package substrate having a plurality of solder balls lands and a resist layer formed on a first side. The resist layer may have a plurality of elliptical openings. Each of the elliptical openings may expose a portion of one of the solder ball lands, respectively.

In a related example embodiment, the solder ball lands may be disposed along at least one direction of the first side, and long axes of the elliptical openings are disposed having a declination of 30° to 60° with respect to the one direction.

In another related example embodiment, the PCB may also have a plurality of other second ball lands and a second resist layer formed on a second side of the package substrate, the second side being opposite the first side. The second resist layer may include a plurality of second elliptical openings. Each of the second elliptical openings may expose a portion of one of the second solder ball lands, respectively. The PCB may also include a mounting region for a semiconductor chip located on the second side of the package substrate.

In another example embodiment, a semiconductor package may include a plurality of first solder ball lands formed on the first side of a package substrate such that at least one of the first solder ball lands is electrically connected to a semiconductor chip. The semiconductor chip may be mounted on a mounting region on a second side of the package substrate, the second side being opposite the first side. A first resist layer may be formed on the first side of the package substrate and have a plurality of first elliptical openings exposing a portion of one of the first solder ball lands, respectively. The solder ball lands may be disposed along at least one direction of the first side and the long axes of the first elliptical openings may have a declination of 30° to 60° with respect to the one direction.

In a related example embodiment, the semiconductor package may include a plurality of second solder ball lands formed on the second side of the package substrate outside a perimeter of the mounting region and may also include a resist layer formed on the second side of the package substrate. The resist layer on the second side may include a plurality of second elliptical openings. Each of the second elliptical openings may expose a portion of one of the second solder ball lands, respectively.

In yet another example embodiment, a multi-stack semiconductor package (MSP) may include at least a first semiconductor package and a second semiconductor package. The first package substrate may include a plurality of first solder ball lands formed on a first side of a first package substrate. At least one of the first solder ball lands may be electrically connected to a first semiconductor chip. The first semiconductor chip may be mounted on a second side of the first package substrate, the second side of the first substrate being opposite the first side of the first package substrate. A plurality of second solder ball lands may be formed on the second side of the first package substrate outside a perimeter of the first semiconductor chip and may connect to at least one of the first solder ball lands. A first resist layer may be formed on the first side of the first package substrate and have a plurality of first openings. Each of the plurality of first openings may expose a portion of one of the first solder ball lands, respectively. The first openings may be elliptical. A second resist layer may be formed on the second side of the first package substrate and have a second plurality of elliptical openings. Each of the second elliptical openings may expose a portion of one of the second solder ball lands, respectively. A plurality of first solder balls may be connected to at least one of the first solder ball lands exposed through the first openings. The second semiconductor package may include a plurality of third solder ball lands formed on the first side of the second package substrate in a pattern corresponding to the second solder ball lands of the first package substrate. At least one of the third solder ball lands may be electrically connected to a second semiconductor chip. The second semiconductor chip may be mounted on the second side of a second package substrate, the second side of the second package substrate being opposite the first side of the second package substrate. A third resist layer may be formed on the first side of the second package substrate and may have a plurality of third elliptical openings. Each of the third elliptical openings may expose a portion of one of the third solder ball lands, respectively. A plurality of second solder balls may be connected to at least one of the third solder ball lands exposed through the third elliptical openings and may also be electrically connected to the second solder ball lands exposed through the elliptical second openings of the first semiconductor package.

### BRIEF DESCRIPTION OF THE DRAWINGS

The above and other features and advantages of the present invention will become more apparent by describing exemplary embodiments in detail with reference to the attached drawings in which:

FIG. 1 is a backside view of the conventional PCB;

FIG. 2 is a backside view of the conventional semiconductor package using the PCB of FIG. 1;

FIG. 3 is a sectional view of a PCB according to an example embodiment of the present invention;

FIG. 4 is a backside view of the PCB of FIG. 3;

FIG. 5 is a sectional view of a PCB according to another example embodiment of the present invention;

FIG. 6 is a frontside view of the PCB of FIG. 5;

FIG. 7 is a sectional view of a semiconductor package according to an example embodiment of the present invention;

FIG. 8 is a backside view of the semiconductor package of FIG. 7;

FIG. 9 is a sectional view of a semiconductor package according to another example embodiment of the present invention; and

FIG. 10 is a sectional view of a multi-stack semiconductor package according to an example embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

The present invention will now be described using example embodiments directed to PCB, semiconductor package, and multi-stack semiconductor package devices. First, a PCB will be described in accordance with an example embodiment of the present invention. Thereafter, example embodiments directed to semiconductor packages will be described in accordance with the present invention. Finally, an example embodiment of a multi-stack semiconductor package in accordance with (the present invention will be described, which may refer to the elements and embodiments disclosed in the descriptions of the PCB and semiconductor packages.

PCB Embodiments

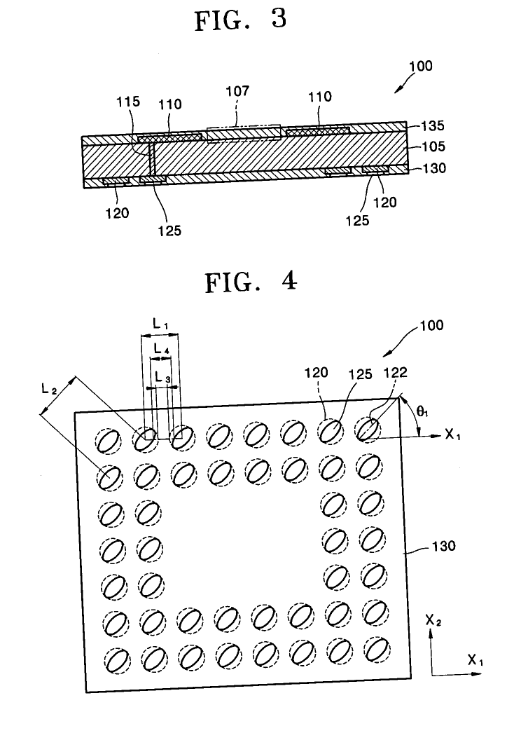

FIG. 3 is a sectional view of a PCB 100 according to an example embodiment of the present invention and FIG. 4 is a backside view of the PCB 100.

Referring to FIG. 3, the PCB 100 includes a package substrate 105 having a semiconductor chip mounting region 107. A metal wiring 110 forming a circuit pattern (not shown) is provided at least on the front side of the package substrate 105. A plurality of solder ball lands 120, electrically connected to the metal wiring 110, is provided on the backside of the package substrate 105. A first resist layer 130 may be provided on the backside of the package substrate 105. The first resist layer 130 may include exposing the solder ball lands 120. Additionally, a second resist layer 135 may be provided on the front side of the package substrate 105.

The package substrate 105 may be formed of a plate shaped insulation resin layer having a front side and a backside. The mounting region 107 may be formed in the central portion of the front side of the package substrate 105. Furthermore, a pad (not shown) may be formed on the mounting region 107.

The metal wiring 110 may be formed around the mounting region 107. The metal wiring 110 may serve as a circuit pattern for connecting external terminals of a semiconductor chip to the solder ball lands 120. The metal wiring 110 may be formed on the front side of the package substrate 105 but may also be formed on the backside thereof. The metal wiring 110 may be connected to the solder ball lands 120 by a plurality of via plugs 115. FIG. 3 does not necessarily illustrate every via plug 115 connected to the solder ball lands 120. The metal wiring 110 may be made of Cu, Al, Ag, Au, or any other appropriate metal or metallic alloy.

The first and second resist layers 130 and 135 may be referred to as photo solder resist layers (PSR). Though the second photo resist layer 135 covers the metal wiring 110 in FIG. 3, the metal wiring 110 may be exposed through a portion of the second photo resist layer 135 on the front side of the package substrate 105.

Referring to FIGS. 3 and 4, the solder ball lands 120 may be arranged along the edges of the package substrate 105. For example, the solder ball lands 120 may be arranged in two lines along axis-directions X1 and X2. The number of the solder ball lands and the number of solder ball lines may be determined based on the degree of integration of a semiconductor chip that may be mounted on the PCB 100. The solder ball lands 120 may be formed in various shapes with a predetermined surface area. For example, the solder ball lands 120 may be formed in a disk shape. The solder ball lands 120 may be formed of a conductive metal; for example, Cu, Al, Au, or Ag, or any other appropriate metal or alloy.

In the case where PCB 100 is used for an MSP, the arrangement of the solder ball lands 120 may be limited. For example, it may be beneficial to provide a number of solder ball lands 120 along the edges of the package substrate 105, so as to increase the arrangement density of the solder ball lands 120, and reduce the pitch L1 between the solder ball lands 120. This may result in a shorter separation distance L3 between the solder ball lands 120.

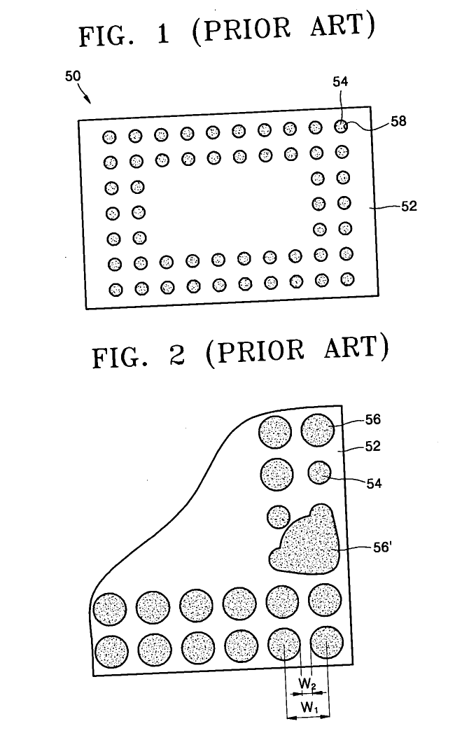

The first resist layer 130 includes elliptical openings 125 exposing an elliptical portion of the solder ball lands 120. The area of the solder ball lands 120 exposed by the elliptical shape (i.e., the area of an opening 125) may have the same exposed area as the conventional solder ball land 54 exposed in the circular shape (i.e., the area of the opening 58) in FIG. 1. The curvature of the elliptical opening 125, the length and/or the angle of the long elliptical axis 122 may be adjusted, to increase the separation distance L3 between the solder ball lands 120.

The openings 125 may be arranged to form a declination angle with respect to a direction (e.g., X1 axis-direction or X2 axis-direction) in which the solder ball lands 120 are arranged. For example, a declination θ1 formed by the long axes 122 of the openings 125 and an X1 axis may be in the range of 30-60°. In another example, the long axes of the openings 125 may be arranged at a declination of 30-60° with respect to the edges of the package substrate 105. In yet another example, the long axes 122 of the openings 125 may be arranged in the diagonal direction of the solder ball lands 120 because the diagonal distances L2 of the solder ball lands 120 may provide the largest separation distances between the solder ball lands 120.

As a result, the shortest separation distance L4 between the exposed solder ball lands 120 is greater than the shortest separation distance L3 between the solder ball lands 120 (not exposed). The increase of the shortest exposed separation distance L4 increases a separation distance between solder balls (not shown) of a semiconductor package as will be described below, making it possible to reduce the likelihood of generating a short-circuit between the solder balls. Therefore, the PCB 100 may include a higher density of solder ball lands 120 and may make it possible to mount a higher integration semiconductor chip on the PCB 100.

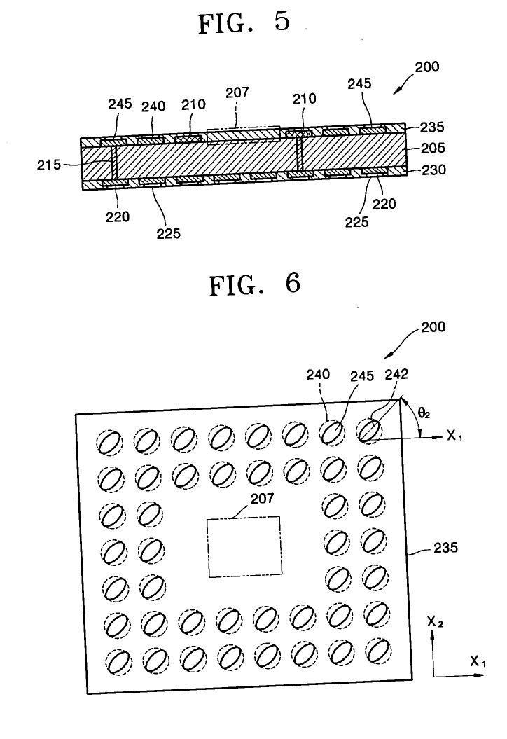

FIG. 5 is a sectional view of a PCB 200 according to another embodiment of the present invention and FIG. 6 is a plan view of the PCB 200. This embodiment of the present invention is a modification of the previous embodiment of the present invention. Therefore, the description of the PCB 200 may refer to the description of the PCB 100 (FIG. 3). Reference numerals differ only in their 100's position in the embodiments represent correspondingly similar elements.

Referring to FIG. 5, the PCB 200 includes a package substrate 205 having a mounting region 207. A metal wiring 210 forming a circuit pattern (not shown) may be provided at least on the front side of the package substrate 205. A plurality of first solder ball lands 220 electrically connected to the metal wiring 210 may be provided on the backside of the package substrate 205, and second solder ball lands 240 may be provided on the front side of the package substrate 205. A first resist layer 230 on the backside of the package substrate 205 may include first openings 225, and the second resist layer 235 on the front side of the package substrate 205 may include first openings 245.

The metal wiring 210 may include via plugs 215. The metal wiring 210 may be connected to some of the first solder ball lands 220 through the via plugs 215. Moreover, some of the first solder ball lands 220 may be connected to the second solder ball lands 240 through other via plugs 215. In FIG. 5, the via plugs 210 and 215 have been exemplarily illustrated.

In an example embodiment, the first solder ball lands 220 may be similar to the solder ball lands 120 of the embodiment illustrated in FIG. 4. However, the solder ball lands 120 of the embodiment illustrated in FIG. 4 are arranged in two lines, but the first solder ball lands 220 may be arranged in more lines. The first solder ball lands 220 may be arranged and formed to function similarly to the solder ball lands 120 of the embodiment illustrated in FIG. 4. The first resist layer 230 may include first elliptical openings 225, and some of the first solder ball lands 220 may be exposed through the first openings 225.

According to another embodiment, the PCB 200 may be used as a lower semiconductor package of an MSP, such that the first openings 225 may be formed in a circular shape as illustrated in FIG. 1 because the PCB 200 for the lower semiconductor package may allow the solder ball lands 220 to be formed over the entire backside of the package substrate 205.

Referring to FIGS. 5 and 6, the second solder ball lands 240 may be arranged along the front edges of the package substrate 205 outside the perimeter of the semiconductor chip mounting region 207. For example, the second solder ball lands 240 may be arranged in two or more lines along X1 and X2 axis-directions. The arrangement density and number of the second solder ball lands 240 may be limited by the size of the mounting region 207.

The second resist layer 235 may include second elliptical opening 245, and some of the second solder ball lands 240 may be exposed in an elliptical shape through the second elliptical openings 245 in the second resist layer 235. The second elliptical openings 245 may be arranged such that the long elliptical axis 242 of the second elliptical opening 245 may be formed having a declination of a angle with respect to a direction (e.g., X1 axis direction or X2 axis direction) in which the solder ball lands 240 are arranged. For example, the long axes of the second opening 245 may be formed having a declination θ2, which may be in the range of 30-60° with respect to the X1-axis. Alternatively, the long axes 242 of the second openings 245 may be arranged to have a declination of 30-60° with respect to the edge of the package substrate 205. In yet another embodiment, the long axes 242 of the openings 245 may be arranged in the diagonal direction of the second solder ball lands 240.

As a result, the shortest separation distance between the second exposed solder ball lands 240 is greater than the shortest separation distance between the second solder ball lands 240 (not exposed), as similarly described with reference to FIG. 4. Increasing the shortest separation distance between the exposed second solder ball lands 240 increases a separation distance between solder balls (not shown) of a semiconductor package, and reduces the likelihood of a short-circuit between the solder balls. Therefore, the PCB 200 may include a higher density of solder ball lands 240 and thus may be used for a lower semiconductor package (not shown) of an MSP on which a high integration semiconductor chip (not shown) is mounted.

Semiconductor Package

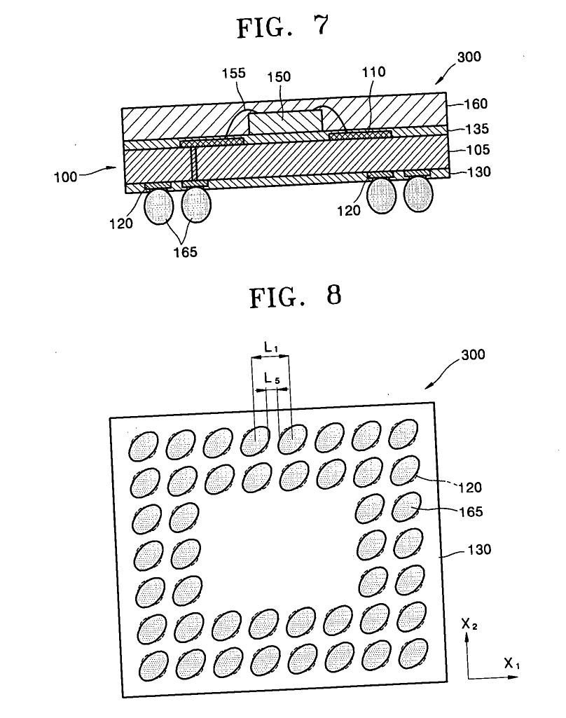

FIG. 7 is a sectional view of a semiconductor package 300 according to an example embodiment of the present invention and FIG. 8 is a backside view of the semiconductor package 300.

As shown, semiconductor package 300 may include PCB 100 according to the embodiment of the present invention shown in FIG. 3. Like reference numerals in the drawings denote like elements or similar elements.

Referring to FIG. 7, the semiconductor package 300 includes a semiconductor chip 150 mounted on the front side of a package substrate 105. The semiconductor chip 150 may be mounted on a mounting region (107 in FIG. 3) of the package substrate 105. The semiconductor chip 150 may be electrically connected to the metal wiring 110. For example, a metal pad (not shown) of the semiconductor chip 150 may be connected to the metal wiring 110 using a conductive wire 155.

The semiconductor package 300 may further include a molding member 160 covering the semiconductor chip 150 and the conductive wire 155. The molding member 160 may protect the semiconductor chip 150 from physical impact or outside moisture. Referring to FIG. 7, the molding member 160 may cover the entire front side of the package substrate 105 or cover a portion of the front side of the package substrate 105 including the semiconductor chip 150.

Referring to FIGS. 7 and 8, the semiconductor package 300 may further include a plurality of solder balls 165 connected to solder ball lands 120 exposed through openings (125 of FIG. 3). The semiconductor package 300 may have a BGA structure. The solder balls 165 may have an oval shape. Alternatively, solder balls 165 may have a circular shape originally, but may be transformed according to the elliptical shape of the exposed solder ball lands 120 during the reflow process and may obtain an oval shape. Therefore, the arrangement of the solder balls 165 may be almost the same as that of the openings (125 in FIG. 3).

Even when the shortest pitches L1 of the solder balls 165 are the same as the shortest pitches W1 of the solder balls 56 illustrated in FIG. 1, the shortest separation distance L5 of the solder balls 165 is larger than the shortest separation distance W2 of the solder balls 56 illustrated in FIG. 1. For example, if the diameter of the solder ball 165 is 0.32 mm, a shortest pitch L1 between the solder balls 165 is 0.65 mm, and the ratio of the short axis to the long axis of the elliptical cross-section of the solder ball 165 is 1:2, a shortest separation distance L5 between the solder balls 165 may be 0.19 mm. Under the same conditions, a separation distance W2 between the solder balls 56 illustrated in FIG. 1 may be 0.15 mm.

Therefore, the separation distance L5 between the solder balls 165 may be increased by more than 30% compared to the conventional art. Moreover, it is possible to increase the separation distance L5 between the solder balls 165 even more by adjusting the ratio of the long axis to the short axis of the elliptical opening (125 in FIG. 3). Accordingly, it is possible to reduce the likelihood of short-circuit between the solder balls 165 during the reflow process. As a result, it is possible to mount a semiconductor chip 150 of higher integration onto the semiconductor package 300 and increase the reliability of the semiconductor package 300.

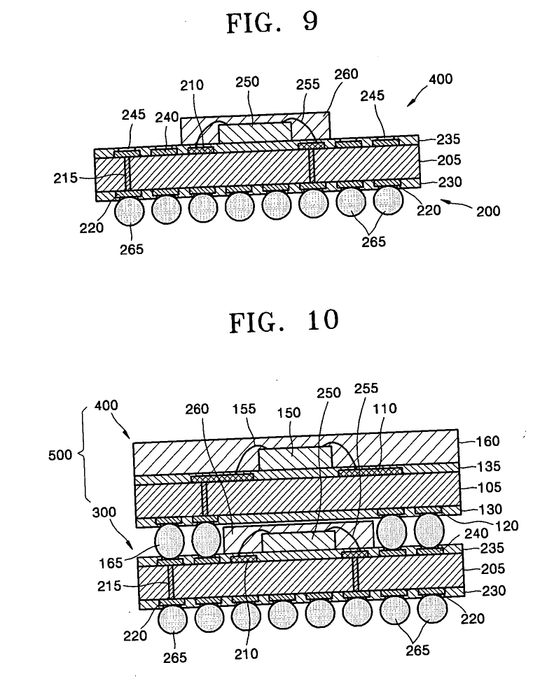

FIG. 9 is a sectional view of a semiconductor package 400 according to another embodiment of the present invention. This embodiment of the present invention is a modification of the previous embodiment of the present invention. Here, the semiconductor package 400 includes the PCB 200 according to the previous embodiment of FIG. 5. Like reference numerals in the drawings denote like or similar elements.

Referring to FIG. 9, the semiconductor package 400 may have a semiconductor chip 250 mounted on the front side of a package substrate 205 of the PCB 200. The semiconductor chip 250 may be mounted on a mounting region (207 in FIG. 5) of the package substrate 205. The semiconductor chip 250 may be electrically connected to a metal wiring 210. For example, a metal pad (not shown) of the semiconductor chip 250 may be connected to the metal wiring 210 using a conductive wire 255. The semiconductor package 400 may further include a molding member 260 covering the semiconductor chip 250 and the conductive wire 255. The molding member 260 may cover a portion of the front side of the package substrate 205 that includes the semiconductor chip 250 and the conductive wires 255.

The semiconductor package 400 may further include a plurality of solder balls 265 connected to solder ball lands 220 exposed through first openings (225 of FIG. 5). The semiconductor package 400 may have a BGA structure. The solder balls 265 may have a circular shape or an oval shape. The solder balls 265 may be formed corresponding to the shape of the first openings (225 of FIG. 5). Where the first openings (225 of FIG. 5) have a circular shape, the solder balls 265 may have a shape similar to a circle. Where the first openings (225 of FIG. 5) have an elliptical shape, the solder balls 265 may have a shape similar to an oval. The semiconductor package 400 may be located at a lowermost layer of an MSP, and in this case, the first openings (225 of FIG. 5) may have a circular shape and the solder balls 265 may have a circular shape.

FIG. 10 is a sectional view of a multi-stack semiconductor package (MSP) 500 according to an embodiment of the present invention. Though the MSP 500 may mount a plurality of semiconductor packages, description is made using an example where two semiconductor packages 300 and 400 are stacked in FIG. 10. FIG. 7 may be referred to for the lower semiconductor package 300. FIG. 9 may be referred to for the upper semiconductor package 400. Like reference numerals in the drawings denote like or similar elements.

Referring to FIG. 10, the solder balls 165 of the upper semiconductor package 400 are electrically connected to second solder ball lands 240 of the lower semiconductor package 300. Since the solder balls 165 are connected to solder ball lands 240 and 120 exposed in an elliptical shape, the solder balls 165 may have an oval shape. For example, the originally circular-shaped solder balls 165 are arranged between the exposed solder ball lands 240 and 120, and subsequently, the solder balls 165 are transformed into an egg shape during the reflow process and may be bonded to the solder ball lands 240 and 120.

As the separation distances between the solder balls 165 connecting the two semiconductor packages 300 and 400 increase, generation of short-circuit between the solder balls 165 may be reduced. When the height of the semiconductor chip 250 increases, the sizes of the solder balls 165 increase, reducing the separation distance between the solder balls 165, which may cause short-circuits between the solder balls 165. However, the increased separation distance between the solder balls may offer the added benefit of allowing for the use of larger solder balls, without an increased risk of a short-circuit.

Alternatively, according to an MSP 500 of the present invention, while a separation distance between the solder balls 165 connecting the two semiconductor packages 300 and 400 can be maintained constant, while increasing the density of the solder balls 165, the number of the solder balls 165 may be increased. Therefore, the MSP 500 according to the example embodiments of the present invention may reliably stack the semiconductor packages 300 and 400.

While the present invention has been particularly shown and described with reference to exemplary embodiments, it will be understood by those of ordinary skill in the art that various changes in form and details may be made without departing from the spirit and scope of the present invention.

What is claimed is:

1. A printed circuit board (PCB) comprising:
a package substrate;
a plurality of first solder ball lands formed on a first side of the package substrate; and
a first resist layer formed on the first side of the package substrate and including a plurality of first elliptical openings, each of the first elliptical openings exposing a portion of one of the first solder ball lands, respectively.

2. The PCB of claim 1, wherein the first solder ball lands are disposed along at least one direction of the first side and the long axes of the first elliptical openings are disposed having a declination of 30-60° with respect to the one direction.

3. The PCB of claim 1, wherein long axes of the first elliptical openings are disposed to face a same direction.

4. The PCB of claim 1, wherein the first solder ball lands are disposed along an edge of the first side of the package substrate and long axes of the first elliptical openings have a declination of 30-60° with respect to the edge of the package substrate.

5. The PCB of claim 4, wherein the declination of the long axes of the first elliptical openings is 45°.

6. The PCB of claim 1, further comprising:
a plurality of second solder ball lands formed on a second side of the package substrate, the second side being opposite the first side; and
a second resist layer formed on the second side of the package substrate and including a plurality of second elliptical openings, each of the second elliptical openings exposing a portion of one of the second solder ball lands, respectively.

7. The PCB of claim 6, wherein the second solder ball lands are disposed along at least one direction of the second side and long axes of the second elliptical openings have a declination of 30-60° with respect to the one direction.

8. The PCB of claim 6, wherein the second solder ball lands are disposed along an edge of the second side of the package substrate and long axes of the second elliptical openings are disposed to form a declination of 30-60° with respect to the edge of the package substrate.

9. the PCB of claim 8, wherein the declination of the long axes of the second elliptical openings is 45°.

10. The PCB of claim 1, further comprising:
a metal wiring disposed on a second side of the package substrate and forming a circuit pattern, the second side being opposite the first side; and
wherein at least one of the first solder ball lands are electrically connected to the metal wiring.

11. The PCB of claim 1, wherein a second side of the package substrate includes a mounting region for a semiconductor chip, the second side being opposite the first side.

12. The PCB of claim 6, wherein the second side of the package substrate includes a mounting region for a semiconductor chip.

13. The PCB of claim 12, wherein the second solder ball lands formed on the second side of the package are formed outside a perimeter of the mounting region.

14. A semiconductor package comprising:
a plurality of first solder ball lands formed on a first side of a package substrate and at least one of the first solder ball lands being electrically connected to a semiconductor chip, the semiconductor chip being mounted on a mounting region on a second side of the package substrate, the second side being opposite the first side; and
a resist layer formed on the first side of the package substrate and having a plurality of first elliptical openings, each of the first elliptical openings exposing a portion of one of the first solder ball lands, respectively.

15. The semiconductor package of claim 14, further comprising:
a plurality of first solder balls respectively connected to the first solder ball lands exposed by the elliptical openings.

16. The semiconductor package of claim 14, wherein the first solder ball lands are disposed along at least one direction of the first side and long axes of the first elliptical openings have a declination of 30-60° with respect to the one direction.

17. The PCB of claim 16, wherein the declination of the long axes of the first elliptical openings is 45°.

18. The semiconductor package of claim 14, wherein long axes of the first elliptical openings are disposed to face a same direction.

19. The semiconductor package of claim 14, wherein the first solder ball lands are disposed along an edge of the first side of the package substrate and long axes of the first elliptical openings have a declination of 30-60° with respect to the edge of the package substrate.

20. The semiconductor substrate of claim 14, further comprising:
a plurality of second solder ball lands formed on the second side of the package substrate outside a perimeter of the mounting region; and
a second resist layer formed on the second side of the package substrate and including a plurality of second elliptical openings, each of the second elliptical openings exposing a portion of one of the second solder ball lands, respectively.

21. The semiconductor package of claim 20, wherein the second solder ball lands are disposed along at least one direction of the second side and long axes of the second elliptical openings have a declination of 30-60° with respect to the one direction.

22. The semiconductor package of claim 20, wherein the second solder ball lands are disposed along an edge of the second side of the package substrate and long axes of the second elliptical openings have a declination of 30-60° with respect to the edge of the package substrate.

23. The PCB of claim 22, wherein the declination of the long axes of the second elliptical openings is 45°.

24. The semiconductor package of claim 15, wherein the first solder balls have an oval shape.

25. The semiconductor package of claim 20, further comprising:
a plurality of second solder balls respectively connected to the second solder ball lands by the elliptical openings.

26. The semiconductor package of claim 25, wherein the second solder balls have an over shape.

27. A multi-stack semiconductor package (MSP) comprising:
at least a first semiconductor package and a second semiconductor package,
the first semiconductor package including,
a plurality of first solder ball lands formed on a first side of a first package substrate and at least one of the first solder ball lands being electrically connected to a first semiconductor chip, the first semiconductor chip being mounted on a second side of the first package substrate, the second side being opposite the first side,
a plurality of second solder ball lands formed on the second side of the first package substrate outside of a perimeter of the first semiconductor chip and connected to at least one of the first solder ball lands,
a first resist layer formed on the first side of the first package substrate and including a plurality of first openings, each of the first openings at least exposing a portion of one of the first solder ball lands, respectively,
a second resist layer formed on the second side of the first package substrate and including a plurality of second elliptical openings, each of the second elliptical openings exposing a portion of one of the second solder ball lands, respectively, and
a plurality of first solder balls connected to at least one of the first solder ball lands exposed through the first openings;
the second semiconductor package including,
a plurality of third solder ball lands formed on a first side of a second package substrate in a pattern corresponding to the second solder ball lands of the first package substrate and at least one of the third solder ball lands being electrically connected to a second semiconductor chip, the second semiconductor chip being mounted on a second side of the second package substrate, the second side of the second package substrate being opposite a first side of the second package substrate,
a third resist layer formed on the first side of the second package substrate and including a plurality of third elliptical openings, each of the third elliptical openings exposing a portion of one of the third solder ball lands, respectively; and
a plurality of second solder balls connected to at least one of the third solder ball lands exposed through the third elliptical openings, and the second solder balls being electrically connected to the second solder ball lands exposed through the second elliptical openings of the first semiconductor package.

28. The MSP of claim 27, wherein the second solder ball lands are disposed along at least one direction of the second side of the first package substrate and long axes of the second elliptical openings are disposed to form a declination of 30-60° with respect to the one direction.

29. The MSPs of claim 28, wherein the declination of the long axes of the second elliptical openings is 45° with respect to the one direction.

30. The MSP of claim 27, wherein the third solder ball lands are disposed along at least one direction of the first side of the second package substrate and long axes of the third elliptical openings are disposed to form a declination of 30-60° with respect to the one direction.

31. The MSP of claim 27 wherein long axes of the second and third elliptical openings are disposed to face a same direction.

32. The MSP of claim 27, wherein the second solder ball lands are disposed along an edge of the second side of the first package substrate and long axes of the second elliptical openings are disposed to form a declination of 30-60° with respect to the edge of the first package substrate.

33. The MSP of claim 32, wherein the declination of the long axes of the second elliptical openings is 45° with respect to the edge of the substrate.

34. The MSP of claim 27, wherein the third solder ball lands are disposed along an edge of the first side of the second package substrate and long axes of the third elliptical openings are disposed to form a declination of 30-60° with respect to the edge of the second package substrate.

35. The MSP of claim 27, wherein the first solder balls have an oval shape.

36. The MSP of claim 27, wherein the second solder balls have an oval shape.
